(19) United States
(12) Patent Application Publication
(10) Pub. No.: US 2025/0084535 A1
(43) Pub. Date: Mar. 13, 2025

(54) SUBSTRATE PROCESSING APPARATUS, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Kazuyuki OKUDA, Toyama (JP); Tomoki IMAMURA, Toyama (JP); Takaaki NODA, Toyama (JP)

(73) Assignee: KOKUSAI ELECTRIC CORPORATION, Tokyo (JP)

(21) Appl. No.: 18/244,616

(22) Filed: Sep. 11, 2023

(30) Foreign Application Priority Data
Sep. 26, 2022 (JP) 2022-152431

(51) Int. Cl. C23C 16/455; C23C 16/44; C23C 16/52; H01J 37/32; H01L 21/02

(52) U.S. Cl. CPC C23C 16/45578; C23C 16/4405; C23C 16/52; H01J 37/32449; H01L 21/02274; H01L 21/0228; H01J 2237/3321

(57) ABSTRACT

A technique including: a process container accommodating a substrate; a first nozzle including a side surface with a first discharge opening directed toward a substrate arrangement region where the substrate is arranged in the process container; a second nozzle including a side surface with a second discharge opening opened to be directed toward at least one of a portion of the side surface of the first nozzle in a range different from a range where the first discharge opening is formed and a space between the portion and an inner wall surface of the process container; a source gas supply system that supplies a source gas into the process container via the first nozzle; and an inert gas supply system that supplies an inert gas into the process container via the second nozzle.

### CROSS-REFERENCE TO RELATED APPLICATIONS

This application is based upon and claims the benefit of priority from Japanese Patent Application No. 2022-152431, filed on Sep. 26, 2022, the entire contents of which are incorporated herein by reference.

### FIELD

The present disclosure relates to a substrate processing apparatus, a method of manufacturing a semiconductor device, and a recording medium.

### DESCRIPTION OF THE RELATED ART

As one of the processes of manufacturing a semiconductor device, a process of processing a substrate in a process container, for example, a process of forming a film on the substrate by supplying a gas to the substrate accommodated in the process container may be performed. At this time, when a deposit adheres to a surface of a member in the process container, for example, to an outer surface of a nozzle that supplies a source or the like, foreign matters (particles) are generated due to the deposit in some cases.

### SUMMARY

The present disclosure is to provide a technique capable of preventing adhesion of a deposit to a surface of a member in the process container.

According to some embodiments of the present disclosure, there is provided a technique including:
a process container accommodating a substrate;
a first nozzle including a side surface in which a first discharge opening is formed, the first discharge opening being opened to be directed toward a substrate arrangement region where the substrate is arranged in the process container;
a second nozzle including a side surface in which a second discharge opening is formed, the second discharge opening being opened to be directed toward at least of a portion of the side surface of the first nozzle in a range different from a range where the first discharge opening is formed and a space between the portion in the range different from the range where the first discharge opening is formed and an inner wall surface of the process container;
a source gas supply system configured to supply a source gas into the process container via the first nozzle; and
an inert gas supply system configured to supply an inert gas into the process container via the second nozzle.

### BRIEF DESCRIPTION OF THE DRAWINGS

FIG. 1 is a schematic configuration diagram of a vertical process furnace of a substrate processing apparatus suitably used in some embodiments of the present disclosure, and is a longitudinal cross-sectional view of a portion of a process furnace.

FIG. 2 is a schematic configuration diagram of the vertical process furnace of the substrate processing apparatus suitably used in some embodiments of the present disclosure, and is a cross-sectional view of a portion of the process furnace taken along line A-A in FIG. 1.

FIG. 3 is a schematic configuration diagram of a controller of the substrate processing apparatus suitably used in some embodiments of the present disclosure, and is a block diagram illustrating a control system of the controller.

FIG. 4 is a view illustrating a processing sequence in some embodiments of the present disclosure.

FIG. 5 is a view illustrating a cleaning sequence in some embodiments of the present disclosure.

FIG. 6 is a view illustrating a sectional configuration diagram of a modified example of the vertical process furnace of the substrate processing apparatus suitably used in some embodiments of the present disclosure.

FIG. 7 is a view illustrating a sectional configuration diagram of another modified example of the vertical process furnace of the substrate processing apparatus suitably used in some embodiments of the present disclosure.

FIG. 8 is a view illustrating a sectional configuration diagram of still another modified example of the vertical process furnace of the substrate processing apparatus suitably used in some embodiments of the present disclosure.

### DETAILED DESCRIPTION

### Embodiments of the Present Disclosure

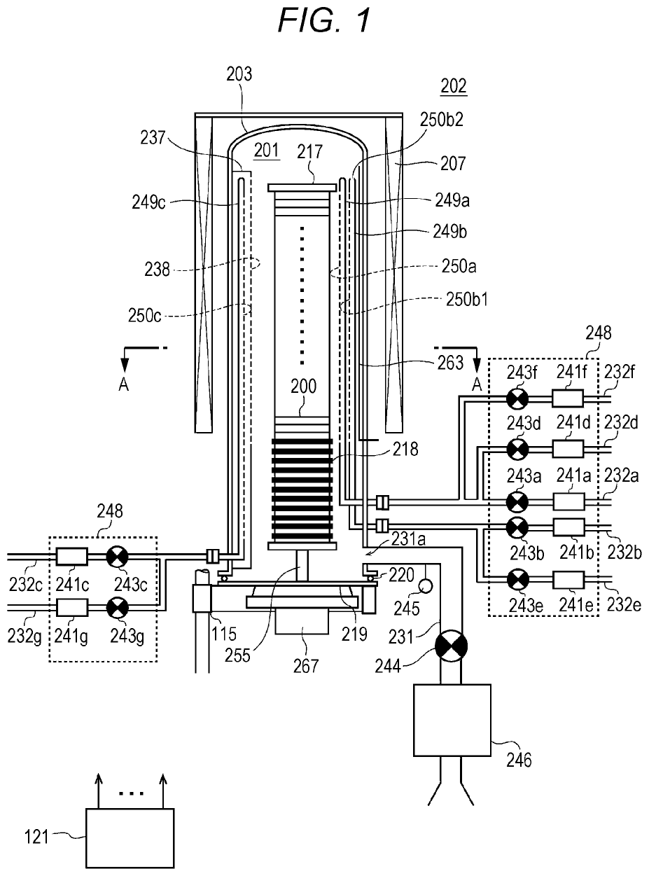

Hereinafter, some embodiments of the present disclosure will be described mainly with reference to FIGS. 1 to 5. The drawings used in the following description are all schematic, and thus, dimensional relationships between constituent elements, ratios between constituent elements, and the like illustrated in the drawings do not necessarily coincide with realities. In addition, a plurality of drawings do not necessarily coincide with one another in dimensional relationships between constituent elements, ratios between constituent elements, and the like.

### (1) Configuration of Substrate Processing Apparatus

As illustrated in FIG. 1, a process furnace 202 includes a heater 207 serving as a temperature regulator. The heater 207 is cylindrical in shape and is vertically installed by being supported by a holding plate. The heater 207 also functions as an activator (exciter) that thermally activates (excites) a gas.

Inside the heater 207, a reaction tube 203 forming a process container is disposed concentrically with the heater 207. The reaction tube 203 is made of, for example, a heat-resistant material such as quartz (SiO₂) or silicon carbide (SiC), and is formed in a cylindrical shape with an upper end closed and a lower end opened. A manifold 209 is disposed below the reaction tube 203 concentrically with the reaction tube 203. A process chamber 201 is formed in a cylindrical hollow portion of the reaction tube 203. The process chamber 201 is configured to be capable of accommodating a plurality of wafers 200 serving as substrates such that the wafers 200 are arranged at a predetermined interval in a direction perpendicular to the surfaces of the wafers 200. The wafers 200 are processed in the process chamber 201. A lid (upper end portion) of the reaction tube 203 is formed in a dome shape.

In the process chamber 201, nozzles 249a, 249b, and 249c serving as first to third suppliers, respectively, are each provided so as to penetrate a lower portion of the reaction tube 203. The nozzle 249b is detachably provided with respect to the reaction tube 203. The nozzles 249a to 249c are also referred to as first to third nozzles, respectively. The nozzles 249a to 249c are each made of, for example, a heat-resistant material such as quartz or SiC. Gas supply pipes 232a to 232c are connected to the nozzles 249a to 249c, respectively. The nozzles 249a to 249c are nozzles independent of one another.

A metal manifold that supports the reaction tube 203 may be provided below the reaction tube 203, and each nozzle may be provided so as to penetrate a side wall of the metal manifold. In this case, an exhaust pipe 231 described later may be further provided in the metal manifold. Even in this case, the exhaust pipe 231 may be provided not in the metal manifold but in the lower portion of the reaction tube 203. As described above, a furnace opening of the process furnace 202 may be made of metal, and nozzles and the like may be attached to the metal furnace opening.

The gas supply pipes 232a to 232c are respectively provided with mass flow controllers (MFCs) 241a to 241c, each serving as a flow rate controller, and valves 243a to 243c, each serving as an opening/closing valve, in this order from the upstream side of a gas flow. A gas supply pipe 232d is connected to the gas supply pipe 232a downstream of the valve 243a. A gas supply pipe 232f is connected to the gas supply pipe 232a downstream of a connection point between the gas supply pipe 232a and the gas supply pipe 232d. A gas supply pipe 232e is connected to the gas supply pipe 232b downstream of the valve 243b. A gas supply pipe 232g is connected to the gas supply pipe 232c downstream of the valve 243c. The gas supply pipes 232d to 232g are respectively provided with MFCs 241d to 241g and valves 243d to 243g in this order from the upstream side of the gas flow. The gas supply pipes 232a to 232g are each made of, for example, a metal material such as SUS.

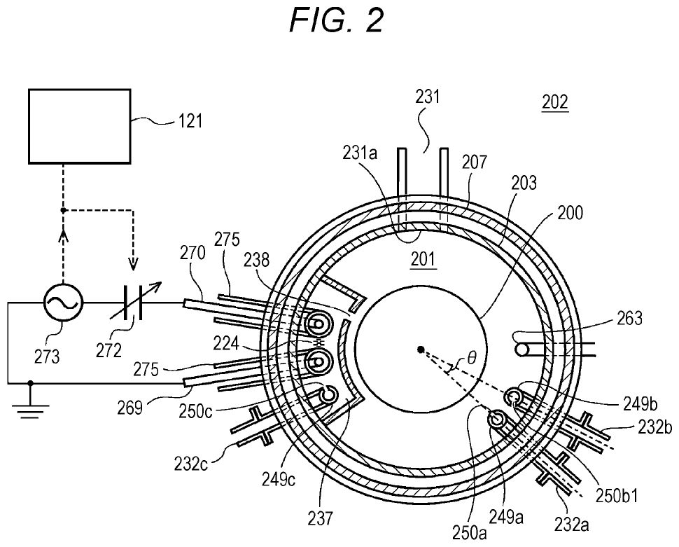

As illustrated in FIG. 2, the nozzles 249a to 249c are provided in an annular space between an inner wall of the reaction tube 203 and the wafer 200 in a plan view. The nozzles 249a to 249c extend upward in an arrangement direction of the wafers 200, along the inner wall of the reaction tube 203 from the lower portion to the upper portion. That is, the nozzles 249a to 249c are provided along the wafer arrangement direction of a wafer arrangement region, in a lateral region of the wafer arrangement region where the wafers 200 are arranged. The lateral region horizontally surrounds the wafer arrangement region.

In a side surface of the nozzle 249a, a first discharge hole (first supply port) serving as a first discharge opening from which a gas is discharged (supplied) is formed along the wafer arrangement direction of the wafer arrangement region. The first discharge hole is formed in a shape including a plurality of gas discharge holes 250a. The plurality of gas discharge holes 250a are formed in the nozzle 249a from one end side to the other end side in the wafer arrangement direction. The gas discharge holes 250a are opened to be directed toward the center of the reaction tube 203, that is, toward the wafer arrangement region, and a gas can be supplied toward the wafers 200. Each of the plurality of gas discharge holes 250a is formed of, for example, a circular hole or an elliptical hole. Regarding the shape of the gas discharge hole, the same applies to second to eighth discharge holes and an upper discharge hole described later.

In a side surface of the nozzle 249b, a second discharge hole (second supply port) serving as a second discharge opening from which a gas is discharged is formed along the wafer arrangement direction of the wafer arrangement region. The second discharge hole is formed in a shape including a plurality of gas discharge holes 250b1. The plurality of gas discharge holes 250b1 are formed in the nozzle 249b from one end side to the other end side in the wafer arrangement direction. As illustrated in FIG. 2, the gas discharge holes 250b1 are opened to be directed toward at least one of (i) a portion of the side surface of the nozzle 249a in a range different from a range where the gas discharge holes 250a are formed (that is, a portion of the outer surface of the nozzle 249a exposed to the inside of the process chamber 201, the portion is different from a portion in which the gas discharge holes 250a are formed in a circumferential direction of the nozzle 249a, hereinafter, the portion is also simply referred to as a “surface with no gas discharge holes”) and (ii) a space (gap) between the surface with no gas discharge holes of the nozzle 249a and an inner wall surface of the reaction tube 203. For example, the gas discharge holes 250b1 are opened to be directed toward a portion of the side surface of the nozzle 249a in a radial direction of the nozzle 249a, the portion is opposite to the range where the gas discharge holes 250a are formed (hereinafter, also referred to as a back surface of the nozzle 249a). Therefore, a gas can be discharged from the gas discharge holes 250b1 toward a back surface side of the nozzle 249a. The gas discharge holes 250b1 are not formed at a position facing the wafer arrangement region. That is, the nozzle 249b does not include a gas discharge hole opened toward the wafer arrangement region, and is configured not to supply a gas toward the wafer arrangement region.

A gas discharge hole 250b2 serving as an upper discharge hole (upper supply port) serving as an upper discharge opening is formed in a distal end (upper end portion) of the nozzle 249b. As described above, the lid of the reaction tube 203 is formed in a dome shape. In a state where a plurality of wafers 200 are vertically arranged in the reaction tube 203, a space (hereinafter, also referred to as an upper dome space) is formed inside the reaction tube 203 at a portion sandwiched between an inner wall of the lid of the reaction tube 203 and the wafer 200 disposed at the upper end portion of the plurality of wafers 200. The gas discharge hole 250b2 is opened to be directed toward the space above the wafer arrangement region, that is, toward the upper dome space. Therefore, a gas can be efficiently discharged toward the upper dome space. An opening area of the gas discharge hole 250b2 is larger than an opening area of each of the gas discharge holes 250b1.

In a side surface of the nozzle 249c, a third discharge hole (third supply port) serving as a third discharge opening from which a gas is discharged is formed along the wafer arrangement direction. The third discharge hole is formed in a shape including a plurality of gas discharge holes 250c. The plurality of gas discharge holes 250c are formed in the nozzle 249c from one end side to the other end side in the wafer arrangement direction of the wafer arrangement region. As illustrated in FIG. 2, the gas discharge holes 250c are opened to be directed toward the center of a buffer chamber 237 described later.

As illustrated in FIG. 2, the nozzles 249a and 249b are provided at positions adjacent to each other along the circumferential direction of the wafers 200 arranged in the wafer arrangement region. Specifically, the nozzles 249a and 249b are disposed at positions where a center angle θ (center angle θ with respect to an arc with centers of the nozzles 249a and 249b as both ends) formed by a straight line (first straight line) connecting the center of the wafer 200 and the center of the nozzle 249a and a straight line (second straight line) connecting the center of the wafer 200 and the center of the nozzle 249b is an acute angle, for example, an angle within a range of 10 to 30° and preferably within a range of 10 to 20° in a plan view.

The nozzle 249c is provided in the buffer chamber 237 serving as a gas distribution space. The buffer chamber 237 is provided in the annular space between the inner wall of the reaction tube 203 and the wafers 200 at a portion from the lower portion to the upper portion of the inner wall of the reaction tube 203, along the arrangement direction of the wafers 200. That is, the buffer chamber 237 is provided along the wafer arrangement region, in the lateral region of the wafer arrangement region. The lateral region horizontally surrounds the wafer arrangement region. Gas discharge holes 238 from which a gas is discharged are formed in an end portion of the wall of the buffer chamber 237 adjacent to the wafers 200. The gas discharge holes 238 are opened to be directed toward the wafer arrangement region. Therefore, a gas can be discharged toward the wafers 200. A plurality of gas discharge holes 238 are formed in the buffer chamber 237 from one end side to the other end side in the wafer arrangement direction of the wafer arrangement region.

A source is supplied from the gas supply pipe 232a into the process chamber 201 via the MFC 241a, the valve 243a, and the nozzle 249a. The source is used as one of the film-forming agents.

A reactant is supplied from the gas supply pipe 232c into the process chamber 201 via the MFC 241c, the valve 243c, and the nozzle 249c. The reactant is used as one of the film-forming agents.

A first cleaning gas is supplied from the gas supply pipe 232d into the process chamber 201 via the MFC 241d, the valve 243d, and the nozzle 249a. The first cleaning gas is used as one of the cleaning agents.

An additive gas that reacts with a cleaning gas is supplied from the gas supply pipe 232e into the process chamber 201 via the MFC 241e, the valve 243e, and the nozzle 249b. The additive gas cannot perform a cleaning action alone. However, when reacting with the first cleaning gas, the additive gas generates a predetermined active species and acts to enhance the cleaning action of the first cleaning gas. The additive gas is used as one of the cleaning agents.

An inert gas is supplied from the gas supply pipes 232b, 232f, and 232g into the process chamber 201 via the MFCs 241b, 241f, and 241g, the valves 243b, 243f, and 243g, the nozzles 249b, 249a, and 249c, respectively. The inert gas acts as a purge gas, a carrier gas, a diluent gas, or the like.

A source supply system (source gas supply system) mainly includes the gas supply pipe 232a, the MFC 241a, and the valve 243a. A reactant supply system (reactant gas supply system) mainly includes the gas supply pipe 232c, the MFC 241c, and the valve 243c. A first cleaning gas supply system mainly includes the gas supply pipe 232d, the MFC 241d, and the valve 243d. An additive gas supply system mainly includes the gas supply pipe 232e, the MFC 241e, and the valve 243e. An inert gas supply system mainly includes the gas supply pipes 232b, 232f, and 232g, the MFCs 241b, 241f, and 241g, and the valves 243b, 243f, and 243g. The source supply system, the reactant supply system, or both are also referred to as a film-forming agent supply system. The first cleaning gas supply system, the additive gas supply system, or both are also referred to as a cleaning agent supply system.

One or each of the various supply systems described above may be configured as an integrated supply system 248 in which the valves 243a to 243g, the MFCs 241a to 241g, and the like are integrated. The integrated supply system 248 is connected to each of the gas supply pipes 232a to 232g, and is configured such that the operations of supplying various substances (various gases) into the gas supply pipes 232a to 232g, that is, opening/closing operations of the valves 243a to 243g, flow rate regulating operations by the MFCs 241a to 241g, and the like are controlled by a controller 121 described later. The integrated supply system 248 is configured as an integral or splittable integrated unit, and can be attached to or detached from the gas supply pipes 232a to 232g and the like on an integrated unit basis. Therefore, the integrated supply system 248 is configured so that maintenance, replacement, expansion, and the like of the integrated supply system 248 can be performed on an integrated unit basis.

As illustrated in FIG. 2, in the buffer chamber 237, two rod-shaped electrodes, 269 and 270, each formed of an electric conductor with an elongated structure are provided to extend upward in the arrangement direction of the wafers 200, along the inner wall of the reaction tube 203 from the lower portion to the upper portion. The rod-shaped electrodes 269 and 270 are provided in parallel with the nozzle 249c. The rod-shaped electrodes 269 and 270 are each protected by being covered by an electrode protection tube 275 from the upper portion to the lower portion. Either one of the rod-shaped electrodes 269 or 270 is connected to a high-frequency power supply 273 via a matching device 272, and the other is connected to the ground as a reference potential. Here, the rod-shaped electrode 270 is connected to the high-frequency power supply 273 via the matching device 272, and the rod-shaped electrode 269 is connected to the ground as the reference potential. Plasma is generated in a plasma generation region 224 between the rod-shaped electrodes 269 and 270 by applying radio frequency (RF) power between the rod-shaped electrodes 269 and 270, via the matching device 272 from the high-frequency power supply 273.

The electrode protection tubes 275 each have a structure in which a corresponding one of the rod-shaped electrodes 269 and 270 can be inserted into the buffer chamber 237 in a state where the corresponding rod-shaped electrode is isolated from the atmosphere in the buffer chamber 237. If the concentration of oxygen (O₂) inside the electrode protection tube 275 is approximately equal to the concentration of O₂ of ambient air (atmospheric air), the rod-shaped electrodes 269 and 270 inserted into the respective electrode protection tubes 275 are thermally oxidized by the heater 207. Therefore, by filling the inside of the electrode protection tube 275 with an inert gas or by purging the inside of the electrode protection tube 275 with the inert gas by using an inert gas purge mechanism, the concentration of O₂ inside the electrode protection tube 275 can be reduced, thus preventing oxidation of the rod-shaped electrodes 269 and 270.

A plasma exciter (activation mechanism) that excites (activates) a gas to a plasma state mainly includes the rod-shaped electrodes 269 and 270 and the electrode protection tubes 275. The matching device 272 and the high-frequency power supply 273 may be considered to be included in the plasma exciter. In addition, the buffer chamber 237 may be considered to be included in the exciter.

The exhaust port 231a from which the atmosphere inside the process chamber 201 is exhausted is formed in a lower portion of a side wall of the reaction tube 203. The exhaust port 231a may be formed from the lower portion of the side wall of the reaction tube 203 to an upper portion thereof along the side wall, that is, along the wafer arrangement region. An exhaust pipe 231 is connected to the exhaust port 231a. A vacuum pump 246 serving as a vacuum exhaust is connected to the exhaust pipe 231 via a pressure sensor 245 serving as a pressure detector that detects the pressure in the process chamber 201 and an auto pressure controller (APC) valve 244 serving as a pressure regulator. The APC valve 244 is configured to be capable of performing vacuum exhaust and stopping the vacuum exhaust inside the process chamber 201 by opening/closing the valve in a state where the vacuum pump 246 is operated, and to be capable of regulating the pressure in the process chamber 201 by regulating the degree of valve opening, on the basis of pressure information detected by the pressure sensor 245 in a state where the vacuum pump 246 is operated. An exhaust system mainly includes the exhaust pipe 231, the APC valve 244, and the pressure sensor 245. The vacuum pump 246 may be considered to be included in the exhaust system.

A seal cap 219 serving as a furnace opening lid capable of airtightly closing a lower end opening of the reaction tube 203 is provided below the reaction tube 203. The seal cap 219 is made of, for example, a metal material such as SUS, and is formed in a disk shape. An O-ring 220 serving as a seal member in contact with the lower end of the reaction tube 203 is provided on an upper surface of the seal cap 219. A rotator 267 that rotates a boat 217, described later, is disposed below the seal cap 219. A rotation shaft 255 of the rotator 267 penetrates the seal cap 219 and is connected to the boat 217. The rotator 267 is configured to rotate the boat 217 to rotate the wafers 200. A boat elevator 115 serving as an elevator mechanism, which is disposed outside the reaction tube 203, is configured to vertically raise and lower the seal cap 219. The boat elevator 115 is configured as a transfer device (transfer mechanism) that loads the wafers 200 into the process chamber 201 or unloads (transfers) the wafers 200 from the process chamber 201 by raising and lowering the seal cap 219.

The boat 217 serving as a substrate support is configured to support a plurality of, for example, 25 to 200 wafers 200 in multiple stages, that is, to arrange the wafers 200 at intervals, while the wafers 200 are aligned in the vertical direction in a horizontal posture in a state where the centers aligned with one another. The boat 217 is made of, for example, a heat-resistant material such as quartz or SiC. Heat insulating plates 218 each made of, for example, a heat-resistant material such as quartz or SiC are supported on a lower portion of the boat 217 in multiple stages.

A temperature sensor 263 serving as a temperature detector is disposed in the reaction tube 203. By regulating the degree of energization to the heater 207 on the basis of temperature information detected by the temperature sensor 263, a desired temperature distribution can be achieved in the process chamber 201. The temperature sensor 263 is provided along the inner wall of the reaction tube 203.

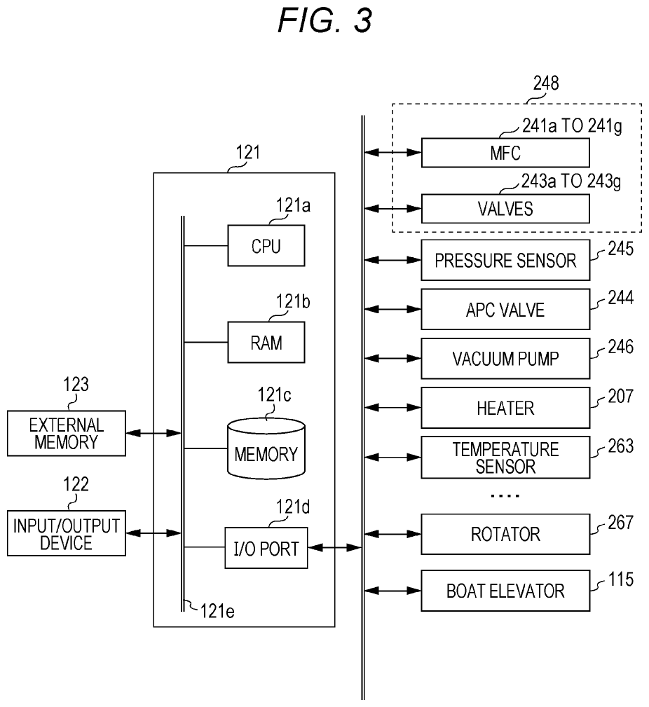

As illustrated in FIG. 3, the controller 121 serving as a control means is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 configured as, for example, a touch panel or the like is connected to the controller 121. In addition, an external memory 123 can be connected to the controller 121.

The memory 121c includes, for example, a flash memory, a hard disk drive (HDD), a solid state drive (SSD), or the like. In the memory 121c, a control program that controls the operation of a substrate processing apparatus, a process recipe in which procedures, conditions, and the like of substrate processing described later are described, and the like are readably recorded and stored. The process recipe is combined so as to function as a program that allows the controller 121 to cause the substrate processing apparatus to perform each procedure in the substrate processing described later to obtain a predetermined result. Hereinafter, the process recipe, the control program, and the like are also collectively and simply referred to as a program. The process recipe is also simply referred to as a recipe. When the term “program” is used in the present specification, it may indicate a case of including the recipe alone, a case of including the control program alone, or a case of including both the recipe and the control program. The RAM 121b is configured as a memory area (work area) in which the program, data, and the like read by the CPU 121a are temporarily stored.

The I/O port 121d is connected to the MFCs 241a to 241g, the valves 243a to 243g, the pressure sensor 245, the APC valve 244, the vacuum pump 246, the temperature sensor 263, the heater 207, the rotator 267, the boat elevator 115, and the like described above.

The CPU 121a is configured to be capable of reading the control program from the memory 121c and executing the control program, and reading the recipe from the memory 121c in response to an input or the like of an operation command from the input/output device 122. The CPU 121a is configured to be capable of controlling, in accordance with the content of the read recipe, flow rate regulating operations of various substances (various gases) by the MFCs 241a to 241g, opening/closing operations of the valves 243a to 243g, an opening/closing operation of the APC valve 244, a pressure regulating operation by the APC valve 244 based on the pressure sensor 245, start and stop of the vacuum pump 246, a temperature regulating operation of the heater 207 based on the temperature sensor 263, a rotating operation and a rotation speed regulating operation of the boat 217 by the rotator 267, a raising/lowering operation of the boat 217 by the boat elevator 115, and the like.

The controller 121 can be configured by installing the above-described program recorded and stored in the external memory 123 into the computer. Examples of the external memory 123 include a magnetic disk such as an HDD, an optical disk such as a CD, a magneto-optical disk such as an MO, a semiconductor memory such as a USB memory or an SSD, and the like. The memory 121c and the external memory 123 are configured as computer-readable recording media. Hereinafter, the memory 121c and the external memory 123 are collectively and simply referred to as a recording medium. When the term “recording medium” is used in the present specification, it may indicate a case of including the memory 121c alone, a case of including the external memory 123 alone, or a case of including both the memory 121c and the external memory 123. Furthermore, the program may be provided to the computer by using a communication means such as the Internet or a dedicated line without using the external memory 123.

### (2) Substrate Processing Process

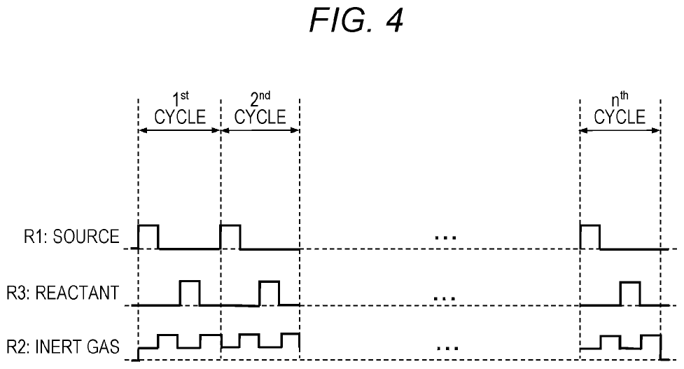

As one of the processes of manufacturing a semiconductor device using the substrate processing apparatus described above, an example of a method of processing a substrate, that is, a processing sequence of forming a film on the wafer 200 serving as a substrate will be described mainly with reference to FIG. 4. In the following description, the operation of each constituent included in the substrate processing apparatus is controlled by the controller 121.

The processing sequence in some embodiments illustrated in FIG. 4 includes a step of forming a film on a wafer 200 by performing a cycle a predetermined number of times (n times, n being an integer of one or more), the cycle including:
(a) a step (source supply step) of supplying a source to the wafer 200 in the process container; and
(b) a step (reactant supply step) of supplying a reactant to the wafer 200 in the process container, performed non-simultaneously, in which
an inert gas is supplied from the nozzle 249b, different from the nozzle 249a that supplies the source, toward at least one of (i) the portion of the side surface of the nozzle 249a in a range different from a range where the gas discharge holes 250a are formed and (ii) the space between the portion of the nozzle 249a in the range different from the range where the gas discharge holes 250a are formed and the inner wall surface of the reaction tube 203 in (a).

In the processing sequence illustrated in FIG. 4, an example is illustrated in which, in (a), a source is supplied from the nozzle 249a to the wafer 200 in the process container and an inert gas is supplied from the nozzle 249b, different from the nozzle 249a, toward at least one of (i) the portion of the side surface of the nozzle 249a in a range different from the range where the gas discharge holes 250a are formed and (ii) the space between the portion of the nozzle 249a in the range different from the range where the gas discharge holes 250a are formed and the inner wall surface of the reaction tube 203.

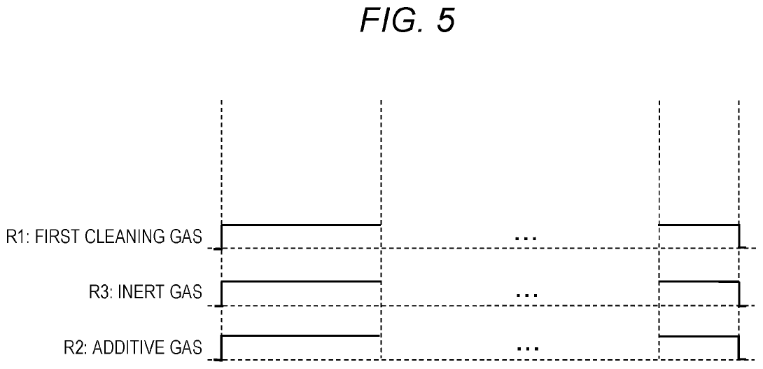

In FIG. 4, the nozzles 249a to 249c are denoted as R1 to R3, respectively, for convenience. A similar expression will be used for each nozzle in FIG. 5 illustrating a cleaning sequence described later.

In the present specification, such a processing sequence (gas supply sequence) may be expressed as follows for convenience. A similar expression will be used in the following description of other embodiments, modified examples, and the like.
(R1: source→R3: plasma exciting reactant)×n

In the processing sequence illustrated in FIG. 4, an example is illustrated in which a cycle including performing (a) and (b) in this order is performed a predetermined number of times (n times). In this case, n is an integer of one or more. In FIG. 4, an example is illustrated in which a space (inside the process container) in which the wafers 200 are present is further purged with the inert gas after performing (a) and before performing (b). In addition, when the cycle is performed a plurality of times, the inside of the process container may be purged with the inert gas after performing (b) and before performing (a). By performing at least one of the above purge processes, it is possible to prevent mixture of the gases in the process container, an unintentional reaction due to the mixture, generation of particles, and the like.

The term “wafer” used in the present specification may mean the wafer itself, or a laminate of a wafer and a predetermined layer or film formed on the surface of the wafer. The phrase “surface of a wafer” used in the present specification may mean a surface of the wafer itself or a surface of a predetermined layer or the like formed on the wafer. The expression “form a predetermined layer on a wafer” in the present specification may mean that a predetermined layer is directly formed on a surface of the wafer itself or that a predetermined layer is formed on a layer or the like formed on the wafer. The term “substrate” used in the present specification is synonymous with the term “wafer”.

The term “agent” used in the present specification includes at least one of a gaseous substance and a liquid substance. The liquid substance includes a mist substance. That is, the film-forming agents (the source and the reactant) may each include a gaseous substance, a liquid substance such as a mist substance, or both a gaseous substance and a liquid substance.

The term “layer” used in the present specification includes at least one of a continuous layer and a discontinuous layer. A layer formed in each step described later may include a continuous layer, a discontinuous layer, or both a continuous layer and a discontinuous layer.

### (Wafer Charge and Boat Load)

When a plurality of wafers 200 are charged on the boat 217 (wafer charge), the boat 217 on which the plurality of wafers 200 are supported is lifted up by the boat elevator 115 and is loaded into the process chamber 201 (boat load) as illustrated in FIG. 1. In this state, the lower end of the reaction tube is sealed by the seal cap 219 with the O-ring 220 interposed therebetween. In this manner, the wafers 200 are prepared in the process chamber 201.

### (Pressure Regulation and Temperature Regulation)

After the boat load is finished, the inside of the process chamber 201, that is, the space in which the wafers 200 are present is vacuum-exhausted (decompression-exhausted) by the vacuum pump 246 so as to achieve a desired pressure (vacuum degree). At this time, the pressure in the process chamber 201 is measured by the pressure sensor 245, and the APC valve 244 is feedback-controlled on the basis of the measured pressure information. In addition, wafers 200 in the process chamber 201 are heated by the heater 207 so as to achieve a desired processing temperature. At this time, the degree of energization to the heater 207 is feedback-controlled on the basis of the temperature information detected by the temperature sensor 263 so as to achieve a desired temperature distribution in the process chamber 201 (temperature regulation). In addition, rotation of the wafers 200 by the rotator 267 is started. The exhaust in the process chamber 201, the heating of the wafers 200, and the rotation of the wafers 200 each continue at least until the processing of the wafers 200 is finished.

### (Film Forming Step)

Thereafter, the following source supply step and reactant supply step are sequentially executed.

### [Source Supply Step]

In this step, a source (source gas) is supplied to the wafers 200 as a film-forming agent.

Specifically, the valve 243a is opened to cause the source to flow into the gas supply pipe 232a (step A). The flow rate of the source is regulated by the MFC 241a. Then, the source is supplied into the process chamber 201 through the plurality of gas discharge holes 250a formed in the side surface of the nozzle 249a, and is exhausted from the exhaust port 231a. At this time, the source is supplied to the wafers 200 from the lateral side of the wafers 200 (source supply).

In addition, while the source is supplied into the process chamber 201 (during execution of step A), the valve 243b is opened to cause the inert gas to flow into the gas supply pipe 232b at a first flow rate (step A′). The flow rate of the inert gas is regulated by the MFC 241b. Then, the inert gas is supplied into the process chamber 201 through the plurality of gas discharge holes 250b1 formed in the side surface of the nozzle 249b and the gas discharge hole 250b2 formed in the distal end of the nozzle 249b, and is exhausted from the exhaust port 231a.

In addition, during execution of step A, the valves 243f and 243g may be opened to supply the inert gas into the process chamber 201 through the plurality of gas discharge holes 250a and 250c formed in the side surfaces of the nozzles 249a and 249c, respectively.

The processing conditions at the time of supplying the source in the source supply step are exemplified as follows.
Processing temperature: 0 to 700° C., preferably room temperature of (25° C.) to 550° C., more preferably 40 to 500° C.
Processing pressure: 1 to 2666 Pa, preferably 665 to 1333 Pa
Source supply flow rate: 1 to 6000 sccm, preferably 2000 to 3000 sccm
Inert gas supply flow rate (gas supply pipe 232b, first flow rate): 300 to 8000 sccm
Inert gas supply flow rate (for each gas supply pipe 232a, 232c): 0 to 10000 sccm
Each gas supply time: one to ten seconds, preferably one to three seconds

In the present specification, the expression of the numerical range such as “0 to 700° C.” means that a lower limit value and an upper limit value are included in the range. Therefore, for example, “0 to 700° C.” means “0° C. or more and 700° C. or less”. The same applies to other numerical ranges. In the present specification, the processing temperature means the temperature of the wafer 200 or the temperature in the process chamber 201, and the processing pressure means the pressure in the process chamber 201. In addition, “processing time” means a time during which the processing is continued. When 0 sccm is included in the supply flow rate, “0 sccm” means a case where the substance (gas) is not supplied. The same applies to the following description.

By supplying, for example, a chlorosilane-based gas to the wafer 200 as the source under the above-described processing conditions, a Si-containing layer containing Cl is formed on an outermost surface of the wafer 200 serving as a base. The Si-containing layer containing Cl is formed on the outermost surface of the wafer 200 by physical adsorption or chemical adsorption of molecules of the chlorosilane-based gas, physical adsorption or chemical adsorption of molecules of a substance obtained by partially decomposing the chlorosilane-based gas, deposition of Si due to thermal decomposition of the chlorosilane-based gas, or the like. The Si-containing layer containing Cl may be an adsorption layer (physical adsorption layer or chemical adsorption layer) of molecules of the chlorosilane-based gas or molecules of a substance obtained by partially decomposing the chlorosilane-based gas, or may be a deposited layer of Si containing Cl. In the present specification, the Si-containing layer containing Cl is also simply referred to as a Si-containing layer. Under the above-described processing conditions, physical adsorption or chemical adsorption of molecules of the chlorosilane-based gas or molecules of a substance obtained by partially decomposing the chlorosilane-based gas on the outermost surface of the wafer 200 occurs predominantly (preferentially), and deposition of Si due to thermal decomposition of the chlorosilane-based gas slightly occurs or hardly occurs. That is, under the above-described processing conditions, the Si-containing layer includes an adsorption layer (physical adsorption layer or chemical adsorption layer) of molecules of the chlorosilane-based gas or molecules of a substance obtained by partially decomposing the chlorosilane-based gas in an overwhelmingly large amount, and slightly or hardly includes a deposition layer of Si containing Cl.

In the source supply step, while the source is supplied into the process chamber 201 from the nozzle 249a, the inert gas is discharged into the process chamber 201 by using the nozzle 249b including the gas discharge holes 250b1 that are opened toward at least one of (i) the portion of the side surface of the nozzle 249a in a range different from the range where the gas discharge holes 250a are formed and (ii) the space between the portion of the nozzle 249a in the range different from the range where the gas discharge holes 250a are formed and the inner wall surface of the reaction tube 203. That is, step A′ is executed in parallel with step A. Accordingly, during execution of step A, the side surface of the nozzle 249a (for example, a portion of the side surface of the nozzle 249a other than the range where the gas discharge holes 250a are formed) can be purged with the inert gas. As a result, it is possible to prevent a source, a substance obtained by decomposing the source, or the like (hereinafter, collectively and simply referred to as “source derived substance” in some cases) from adhering to the side surface (outer surface) of the nozzle 249a. In addition, by preventing adhesion of a substance such as a source to the side surface of the nozzle 249a, it is possible to prevent the reaction between the source derived substance adhered to the side surface of the nozzle 249a and the reactant in the reactant supply step described later. Accordingly, it is possible to prevent the substance generated by the reaction between the source derived substance and the reactant from adhering to the side surface of the nozzle 249a. That is, it is possible to prevent the source derived substance and the substance generated by the reaction between the substance such as a source and the reactant from adhering to the side surface of the nozzle 249a and forming a deposit thereon. As a result, it is possible to prevent generation of particles and the like caused by a deposit, and it is possible to suppress a reduction in film quality and the like finally formed on the wafer 200.

In addition, the nozzles 249a and 249b are provided at positions adjacent to each other along the circumferential direction of the wafer 200. Accordingly, the side surface of the nozzle 249a can be reliably purged with the inert gas discharged from the nozzle 249b (the gas discharge holes 250b1 formed in the nozzle 249b). The same applies to the reactant supply step described later.

In addition, in step A′, the inert gas is discharged into the process chamber 201 by using the nozzle 249b including the plurality of gas discharge holes 250b1 formed from one end side to the other end side in the wafer arrangement direction. Accordingly, the side surface of the nozzle 249a can be purged from one end side to the other end side in the wafer arrangement direction. The same applies to the reactant supply step described later.

In addition, in step A′, the inert gas is discharged into the process chamber 201 by using the nozzle 249b including the gas discharge holes 250b1 opened to be directed toward the back surface of the nozzle 249a. Accordingly, during execution of step A, the back surface of the nozzle 249a and the space between the back surface of the nozzle 249a and the inner wall surface of the reaction tube 203 (hereinafter, also collectively referred to as a “back surface side of the nozzle 249a”) where the source is likely to stagnate can be purged with the inert gas. Therefore, it is possible to prevent the source from stagnating on the back surface side of the nozzle 249a. As a result, it is possible to reliably prevent the source derived substance from adhering to the side surface of the nozzle 249a. The same applies to the reactant supply step described later.

In addition, in step A′, the inert gas is discharged into the process chamber 201 by using the nozzle 249b not including the gas discharge hole opened toward the wafer arrangement region. Accordingly, it is possible to prevent the inert gas from being supplied from the nozzle 249b toward the wafer arrangement region. As a result, even in cases where step A and step A′ are executed in parallel, dilution of the source supplied from the nozzle 249a in the process chamber 201 can be suppressed. By suppressing the dilution of the source in this manner, it is possible to prevent the inert gas supplied from the nozzle 249b in the source supply step from affecting the formation rate of the layer formed on the wafer 200, the thickness and quality of the film finally formed on the wafer 200, and the like. The same applies to the reactant supply step described later.

In addition, in step A′, the inert gas is discharged into the process chamber 201 by using the nozzle 249b including the gas discharge hole 250b2. Accordingly, during execution of step A, the space (upper dome space), which is above the wafer arrangement region in the process chamber 201 and where the source is likely to stagnate, can be efficiently purged with the inert gas. As a result, it is possible to prevent the source derived substance from adhering to the inner wall surface of the reaction tube 203, particularly to the inner wall surface of the lid of the reaction tube 203.

Furthermore, in step A′, the inert gas is discharged into the process chamber 201 by using the nozzle 249b including the gas discharge hole 250b2 with the opening area larger than the opening area of each of the gas discharge holes 250b1. Accordingly, the upper dome space in the process chamber 201 can be more efficiently purged with the inert gas. As a result, it is possible to reliably prevent the source derived substance from adhering to the inner wall surface of the reaction tube 203, particularly to the inner wall surface of the lid of the reaction tube 203. The same applies to the reactant supply step described later.

In this case, a diameter of the gas discharge hole 250b2 is 1.5 mm or more and 3.2 mm or less, for example. Accordingly, the upper dome space in the process chamber 201 can be more efficiently purged with the inert gas. In cases where the diameter of the gas discharge hole 250b2 is less than 1.5 mm, it is difficult to efficiently purge the upper dome space in the process chamber 201 with the inert gas in some cases. If the diameter of the gas discharge hole 250b2 exceeds 3.2 mm, the source in the process chamber 201, particularly in the upper space in the wafer arrangement direction is locally diluted with the inert gas discharged from the gas discharge hole 250b2, leading to a reduction in uniformity (film thickness uniformity, film quality uniformity, and the like) between the wafer surfaces in some cases.

After the Si-containing layer is formed, the valve 243a is closed to stop the supply of the source into the process chamber 201. Then, the inside of the process chamber 201 is vacuum-exhausted to remove the gaseous substance and the like remaining in the process chamber 201 from the inside of the process chamber 201. At this time, the valves 243b, 243f, and 243g are opened to supply the inert gas into the process chamber 201. The inert gas supplied from the nozzles 249a to 249c acts as a purge gas. Accordingly, the inside of the process chamber 201 is purged (purge).

A flow rate (second flow rate) of the inert gas caused to flow into the gas supply pipe 232b in the purge is set to be larger than the flow rate (first flow rate) of the inert gas caused to flow into the gas supply pipe 232b in step A′. That is, the flow rate (second flow rate) of the inert gas supplied from the nozzle 249b in the purge is set to be larger than the flow rate (first flow rate) of the inert gas supplied from the nozzle 249b in step A′.

By setting the flow rate of the inert gas supplied from the nozzle 249b in this manner, the upper dome space in the process chamber 201 can be efficiently purged with the inert gas, particularly, the inert gas discharged from the gas discharge hole 250b2. Accordingly, it is possible to suppress the film formation from being affected by the source remaining in the process chamber 201, particularly, in the upper dome space. For example, it is possible to prevent mixture of the source remaining in the upper dome space and the reactant supplied into the process chamber 201 in the reactant supply step described later, an unintentional reaction (for example, a gas phase reaction or a plasma gas phase reaction) due to the mixture, generation of particles, and the like. As a result, it is possible to suppress a reduction in uniformity between the wafer surfaces. The same applies to the purge in the reactant supply step described later.

The processing conditions in the purge are exemplified as follows.
Processing pressure: 1 to 20 Pa
Inert gas supply flow rate (nozzle 249b, second flow rate): 1 to 10 slm
Inert gas supply flow rate (for each nozzle 249a, 249c): 1 to 10 slm
Inert gas supply time: 1 to 200 seconds, preferably 1 to 40 seconds

The processing temperature at the time of performing purge in this step is preferably similar to the processing temperature at the time of supplying the source.

As the source, for example, a silane-based gas containing silicon (Si) serving as a main element that forms the film formed on the wafer 200 can be used. As the silane-based gas, for example, a gas containing a halogen and Si, that is, a halosilane-based gas can be used. Halogen includes chlorine (Cl), fluorine (F), bromine (Br), iodine (I), and the like. As the halosilane-based gas, for example, the above-described chlorosilane-based gas containing Cl and Si can be used.

As the source, for example, a chlorosilane-based gas such as a monochlorosilane (SiH₃Cl) gas, a dichlorosilane (SiH₂Cl₂) gas, a trichlorosilane (SiHCl₃) gas, a tetrachlorosilane (SiCl₄) gas, a hexachlorodisilane (Si₂Cl₆) gas, or an octachlorotrisilane (Si₃Cl₈) gas can be used. One or more of these gases can be used as the source.

As the source, in addition to the chlorosilane-based gas, for example, a fluorosilane-based gas such as a tetrafluorosilane (SiF₄) gas or a difluorosilane (SiH₂F₂) gas, a bromosilane-based gas such as a tetrabromosilane (SiBr₄) gas or a dibromosilane (SiH₂Br₂) gas, or an iodosilane-based gas such as a tetraiodosilane (SiI₄) gas or a diiodosilane (SiH₂I₂) gas can also be used. One or more of these gases can be used as the source.

As the source, in addition to these gases, for example, a gas containing an amino group and Si, that is, an aminosilane-based gas can also be used. The amino group is a monovalent functional group obtained by removing hydrogen (H) from ammonia, a primary amine, or a secondary amine, and can be represented as —NH₂, —NHR, or —NR₂. Here, R represents an alkyl group, and two Rs in —NR₂ may be the same or different.

As the source, for example, an aminosilane-based gas such as a tetrakis(dimethylamino) silane (Si[N(CH₃)₂]₄) gas, a tris(dimethylamino) silane (Si[N(CH₃)₂]₃H) gas, a bis(diethylamino)silane (Si[N(C₂H₅)₂]₂H₂) gas, a bis(tertiary butylamino)silane (SiH₂[NH(C₄H₉)]₂) gas, or a (diisopropylamino) silane (SiH₃[N(C₃H₇)₂]) gas can also be used. One or more of these gases can be used as the source.

As the inert gas, a nitrogen (N₂) gas or a rare gas such as an argon (Ar) gas, a helium (He) gas, a neon (Ne) gas, or a xenon (Xe) gas can be used. One or more of these gases can be used as the inert gas. The same applies to each step described later.

### [Reactant Supply Step]

After the source supply step is finished, a reactant (reactant gas) is supplied to the wafers 200, that is, to the Si-containing layer formed on the wafers 200 as a film-forming agent. Here, an example will be described in which a nitriding agent (nitriding gas) containing nitrogen is used as the reactant (reactant gas).

Specifically, the valve 243c is opened to cause the nitriding agent to flow into the gas supply pipe 232c (step B). The flow rate of the nitriding agent is regulated by the MFC 241c. Then, the nitriding agent is supplied into the buffer chamber 237 through the plurality of gas discharge holes 250c formed in the side surface of the nozzle 249c. At this time, by applying RF power between the rod-shaped electrodes 269 and 270, the nitriding agent supplied into the buffer chamber 237 can be plasma-excited, and an active species Y generated by plasma-exciting the nitriding agent is supplied into the process chamber 201 from the gas discharge holes 238, and is exhausted from the exhaust port 231a. At this time, the nitriding agent containing the active species Y is supplied to the wafers 200 from the lateral side of the wafers 200 (reactant supply).

In addition, while the reactant is supplied into the process chamber 201 (during execution of step B), the valve 243b may be opened to cause the inert gas to flow into the gas supply pipe 232b at a third flow rate (step B′). At this time, in step B, in which the source is not supplied from the nozzle 249a, the third flow rate is preferably set to be smaller than the first flow rate. The flow rate of the inert gas is regulated by the MFC 241b. Then, the inert gas is supplied into the process chamber 201 through the plurality of gas discharge holes 250b1 formed in the side surface of the nozzle 249b and the gas discharge hole 250b2 formed in the distal end of the nozzle 249b, and is exhausted from the exhaust port 231a.

In addition, during execution of step B, the valves 243f and 243g may be opened to supply the inert gas into the process chamber 201 through the plurality of gas discharge holes 250a and 250c formed in the side surfaces of the nozzles 249a and 249c, respectively.

The processing conditions at the time of supplying nitriding agent in the reactant supply step are exemplified as follows.

Processing temperature: 0 to 700° C., preferably room temperature of (25° C.) to 550° C., more preferably 40 to 500° C.
Processing pressure: 1 to 500 Pa
Nitriding agent supply flow rate: 100 to 10000 sccm, preferably 1000 to 2000 sccm
Inert gas supply flow rate (gas supply pipe 232b, third flow rate): 300 to 8000 sccm
Inert gas supply flow rate (for each gas supply pipe 232a, 232c): 0 to 10000 sccm
Each gas supply time: 1 to 180 seconds, preferably 1 to 60 seconds
RF power: 100 to 1000 W
RF frequency: 13.56 MHz or 27 MHz

By plasma-exciting a nitriding agent and supplying the nitriding agent to the wafer 200 under the above-described processing conditions, at least a part of the Si-containing layer formed on the wafer 200 is nitrided (modified). As a result, a silicon nitride layer (SiN layer) is formed on the outermost surface of the wafer 200 serving as a base as a layer containing Si and N. When the SiN layer is formed, impurities contained in the Si-containing layer, such as Cl, form a gaseous substance containing at least Cl in the process of the modification reaction of the Si-containing layer by the plasma-excited nitriding agent, and are discharged from the inside of the process chamber 201. Accordingly, the SiN layer becomes a layer containing fewer impurities such as Cl than the Si-containing layer formed in the source supply step.

In the reactant supply step, while the reactant is supplied into the process chamber 201 via the nozzle 249c, the inert gas is discharged into the process chamber 201 by using the nozzle 249b including the gas discharge holes 250b1 and 250b2. That is, step B′ is executed in parallel with step B. Accordingly, during execution of step B, the back surface side of the nozzle 249a (for example, a portion of the side surface of the nozzle 249a other than the range where the gas discharge holes 250a are formed) and the upper dome space in the process chamber 201 can be purged with the inert gas. As a result, even in cases where the source derived substance has adhered to at least one of the side surface of the nozzle 249a and the inner wall surface of the lid of the reaction tube 203 in the source supply step, it is possible to prevent the reaction between the source derived substance, which is adhered to at least one of the side surface of the nozzle 249a and the inner wall surface of the lid of the reaction tube 203, and the reactant in the reactant supply step. By preventing such a reaction, it is possible to reliably prevent the substance generated by the reaction between the source derived substance and the reactant from adhering to at least one of the side surface of the nozzle 249a and the inner wall surface of the lid of the reaction tube 203. Accordingly, it is possible to reliably prevent the generation of particles and the like.

After the SiN layer is formed, the valve 243c is closed to stop the supply of the nitriding agent into the process chamber 201. Then, in accordance with processing procedures and processing conditions similar to those for the purge in the source supply step described above, the gaseous substance and the like remaining in the process chamber 201 is removed from the inside of the process chamber 201 (purge). At this time, similarly to the purge in the source supply step, the flow rate (second flow rate) of the inert gas caused to flow into the gas supply pipe 232b in the purge is preferably set to be larger than the flow rate (third flow rate) of the inert gas caused to flow into the gas supply pipe 232b in step B′.

As the reactant, that is, the nitriding agent, for example, a nitrogen (N) and H-containing gas can be used. The N and H-containing gas is an N-containing gas and an H-containing gas. The nitriding agent preferably contains an N—H bond.

As the nitriding agent, for example, a hydrogen nitride-based gas such as an ammonia (NH₃) gas, a diazene (N₂H₂) gas, a hydrazine (N₂H₄) gas, or an N₃H₈ gas can be used. One or more of these gases can be used as the nitriding agent.

As the nitriding agent, in addition to these gases, for example, a nitrogen (N), carbon (C), and H-containing gas can also be used. As the N, C, and H-containing gas, for example, an amine-based gas or an organic hydrazine-based gas can be used. The N, C, and H-containing gas is an N-containing gas, a C-containing gas, an H-containing gas, and an N and C-containing gas.

As the nitriding agent, for example, an ethylamine-based gas such as a monoethylamine (C₂H₅NH₂) gas, a diethylamine ((C₂H₅)₂NH) gas, or a triethylamine ((C₂H₅)₃N) gas, a methylamine-based gas such as a monomethylamine (CH₃NH₂) gas, a dimethylamine ((CH₃)₂NH) gas, or a trimethylamine ((CH₃)₃N) gas, an organic hydrazine-based gas such as a monomethylhydrazine ((CH₃)HN₂H₂) gas, a dimethylhydrazine ((CH₃)₂N₂H₂) gas, or a trimethylhydrazine ((CH₃)₂N₂(CH₃)H) gas, or the like can be used. One or more of these gases can be used as the nitriding agent.

### [Predetermined Number of Times of Execution]

By performing a cycle, in which the source supply step and the reactant supply step described above are performed not simultaneously, that is, not synchronously but alternately, a predetermined number of times (n times, n being an integer of one or more), a silicon nitride film (SiN film) with a predetermined thickness, for example, can be formed on the wafer 200 as a film. Preferably, the cycle described above is repeated a plurality of times. That is, it is preferable to make the SiN layer formed per cycle thinner than a desired thickness of film and repeat the above-described cycle a plurality of times until the thickness of the SiN film formed by stacking the SiN layer becomes the desired thickness. In cases where an N, C, and H-containing gas is used as the nitriding agent, in the reactant supply step, a silicon carbonitride layer (SiCN layer) can also be formed, for example, and a silicon carbonitride film (SiCN film) can also be formed on the surface of the wafer 200 as a film, for example, by performing the above-described cycle a predetermined number of times.

### (After-Purge and Atmospheric Pressure Restoration)

After the SiN film with a desired thickness is formed on the wafer 200, the inert gas serving as a purge gas is supplied from each of the nozzles 249a to 249c into the process chamber 201 and is exhausted from the exhaust port 231a. Accordingly, the inside of the process chamber 201 is purged, and a gas, a reaction by-product, and the like remaining in the process chamber 201 are removed from the inside of the process chamber 201 (after-purge). Thereafter, the atmosphere in the process chamber 201 is replaced with the inert gas (inert gas replacement), so that the pressure in the process chamber 201 is restored to a normal pressure (atmospheric pressure restoration).

### (Boat Unload and Wafer Discharge)

Thereafter, the seal cap 219 is lowered by the boat elevator 115, and the lower end of the reaction tube 203 is opened. Then, the processed wafers 200 are unloaded from the lower end of the manifold 209 to the outside of the reaction tube 203 in a state where the processed wafers 200 are supported by the boat 217 (boat unload). After being unloaded to the outside of the reaction tube 203, the processed wafers 200 are taken out from the boat 217 (wafer discharge).

### (2) Cleaning Processing Process

When the above-described substrate processing, that is, processing of the wafers 200 is performed, a deposit containing the source derived substance, the substance (for example, a silicon nitride such as a SiN film) generated by the reaction between the source derived substance and the reactant, and the like adheres to the surfaces of members in the process container, for example, to the inner wall surface of the reaction tube 203, side surfaces of the nozzles 249a to 249c (outer surfaces), a surface of the boat 217, and the like. Therefore, as one of the processes of manufacturing a semiconductor device, a cleaning processing of removing the above-described deposit (hereinafter, simply referred to as a “deposit” in some cases) adhered to the inside of the process container is performed by using the substrate processing apparatus described above. The cleaning processing is performed after execution of the above-described processing of the wafers 200 a predetermined number of times (one or more times). Hereinafter, a sequence example will be described in which the inside of the process container is cleaned after performing the processing of the wafers 200, mainly with reference to FIG. 5. Also in the following description, the operation of each constituent included in the substrate processing apparatus is controlled by the controller 121.

In the cleaning sequence in some embodiments illustrated in FIG. 5, a step (cleaning step) of removing the deposit adhered to the inside of the process container is performed by supplying the first cleaning gas from one of the nozzles 249a and 249b into the process container after performing the above-described substrate processing, and supplying an additive gas that reacts with the first cleaning gas from the other of the nozzles 249a and 249b, which is different from the one nozzle.

In the cleaning sequence illustrated in FIG. 5, an example is illustrated in which the first cleaning gas is supplied into the process chamber 201 by using the nozzle 249a as the one nozzle, and the additive gas is supplied into the process chamber 201 by using the nozzle 249b as the other nozzle.

In the present specification, the above-described cleaning sequence may be expressed as follows for convenience. A similar expression will be used in the following description of other embodiments, modified examples, and the like.
(R1: first cleaning gas+R2: additive gas)

As in the following cleaning sequence, the first cleaning gas may be supplied into the process chamber 201 by using the nozzle 249b as the one nozzle, and the additive gas may be supplied into the process chamber 201 by using the nozzle 249a as the other nozzle.
(R1: additive gas+R2: first cleaning gas)

### (Boat Load)

The empty boat 217 with the deposit adhered to the surface thereof, that is, the boat 217 not holding the wafers 200 is lifted up by the boat elevator 115 and loaded into the process container with the deposit adhered to the surface thereof, that is, into the process chamber 201. In this state, the lower end of the reaction tube 203 is sealed by the seal cap 219 with the O-ring 220 interposed therebetween.

### (Pressure Regulation and Temperature Regulation)

After the boat load is finished, the inside of the process chamber 201 is vacuum-exhausted (decompression-exhausted) by the vacuum pump 246 so as to achieve a desired pressure (vacuum degree). At this time, the pressure in the process chamber 201 is measured by the pressure sensor 245, and the APC valve 244 is feedback-controlled on the basis of the measured pressure information (pressure regulation). In addition, the inside of the process chamber 201 is heated by the heater 207 so as to achieve a desired processing temperature. At this time, the degree of energization to the heater 207 is feedback-controlled on the basis of the temperature information detected by the temperature sensor 263 so as to achieve a desired temperature distribution in the process chamber 201 (temperature regulation). In addition, rotation of the boat 217 by the rotator 267 is started. The exhaust in the process chamber 201, the heating of the inside of the process chamber 201, and the rotation of the boat 217 each continue at least until the cleaning processing is finished. However, the boat 217 may not have to be rotated.

### (Cleaning Step)

Thereafter, the following cleaning step is executed.

In this step, the first cleaning gas and the additive gas are supplied into the process container in a state where the exhaust in the process container is stopped, that is, in a state where the exhaust system is closed.

Specifically, in a state where the APC valve 244 is fully closed to stop the exhaust in the process chamber 201 by the exhaust system, the valves 243d and 243e are opened to cause the first cleaning gas to flow into the gas supply pipe 232d and the additive gas to flow into the gas supply pipe 232e, respectively. The flow rate of the first cleaning gas is regulated by the MFC 241d. Then, the first cleaning gas is supplied into the process chamber 201 through the gas supply pipe 232a and the plurality of gas discharge holes 250a formed in the side surface of the nozzle 249a (first cleaning gas supply). The flow rate of the additive gas is regulated by the MFC 241e. Then, the additive gas is supplied into the process chamber 201 through the gas supply pipe 232b, the plurality of gas discharge holes 250b1 formed in the side surface of the nozzle 249b, and the gas discharge hole 250b2 formed in the distal end of the nozzle 249b (additive gas supply). At this time, the valves 243b, 243f, and 243g may be opened to supply the inert gas into the process chamber 201 via the nozzles 249a to 249c, respectively.

The processing conditions at the time of supplying the first cleaning gas and the additive gas in the cleaning step are exemplified as follows.
First cleaning gas supply flow rate: 0.5 to 10 slm
Additive gas supply flow rate: 0.5 to 5 slm
First cleaning gas/additive gas flow rate ratio: 0.5 to 2
Inert gas supply flow rate (for each gas supply pipe): 0.01 to 0.5 slm, preferably 0.01 to 0.1 slm
Each gas supply time: 1 to 100 seconds, preferably 5 to 60 seconds
Processing temperature: less than 400° C., preferably 200 to 350° C.

By supplying the first cleaning gas, the additive gas, and the like into the process chamber 201 in a state where the exhaust system is closed, the pressure in the process chamber 201 starts to increase. The pressure (ultimate pressure) in the process chamber 201 that is finally reached by continuing the gas supply is set to a pressure within a range of 1330 to 53320 Pa, preferably within a range of 9000 to 15000 Pa, for example.

When the pressure in the process chamber 201 increases to a predetermined pressure, the supply of the first cleaning gas and the additive gas into the process container is stopped in a state where the exhaust in the process container is stopped, and a state where the first cleaning gas and the additive gas are enclosed in the process container is maintained. Specifically, in a state where the APC valve 244 is fully closed, the valves 243d and 243e are closed to stop the supply of the first cleaning gas and the additive gas into the process chamber 201, and this state is maintained for a predetermined time. At this time, the valves 243b, 243f, and 243g are simultaneously opened to supply the inert gas into the gas supply pipes 232b, 232f, and 232g, respectively. The flow rate of the inert gas is regulated by the MFCs 241b, 241f, and 241g. Then, the inert gas is supplied into the process chamber 201 via the nozzles 249a to 249c. The flow rates of the inert gas supplied from the nozzles 249a to 249c are, for example, set to be identical.

The processing conditions at the time of enclosing the first cleaning gas and the additive gas in the cleaning step are exemplified as follows.
Inert gas supply flow rate (for each gas supply pipe): 0.01 to 0.5 slm, preferably 0.01 to 0.1 slm
Enclosure time: 10 to 200 seconds, preferably 50 to 120 seconds

Other processing conditions are similar to the processing conditions used at the time of supplying the first cleaning gas and the additive gas, except that the pressure in the process chamber 201 continues to slightly increase due to the supply of the inert gas into the process chamber 201.

By supplying a fluorine-based gas, for example, as the first cleaning gas and a nitrogen oxide-based gas, for example, as the additive gas under the processing procedures and processing conditions described above, the first cleaning gas and the additive gas can be mixed and reacted in the process chamber 201. With this reaction, it is possible to generate active species such as, for example, fluorine radical (F*) and nitrosyl fluoride (FNO) (hereinafter, also collectively referred to as FNO or the like) in the process chamber 201. As a result, a mixed gas obtained by adding FNO or the like to the fluorine-based gas is present in the process chamber 201. The mixed gas obtained by adding FNO or the like to the fluorine-based gas comes into contact with members in the process chamber 201, for example, the inner wall of the reaction tube 203, the side surfaces of the nozzles 249a to 249c, the surface of the boat 217, and the like. At this time, the deposit adhered to the members in the process chamber 201 can be removed by a thermochemical reaction (etching reaction). The FNO or the like acts to promote etching reaction by the fluorine-based gas and increase an etching rate of the deposit, that is, to assist the etching.

In the cleaning step, the additive gas is supplied into the process chamber 201 by using the nozzle 249b including the gas discharge holes 250b1 that are opened toward at least one of (i) the portion of the side surface of the nozzle 249a in a range different from the range where the gas discharge holes 250a are formed and (ii) the space between the portion of the nozzle 249a in the range different from the range where the gas discharge holes 250a are formed and the inner wall surface of the reaction tube 203. Accordingly, the FNO or the like can be preferentially generated in the vicinity of the nozzle 249a. As a result, the etching rate can be increased in the vicinity (particularly on the back surface side) of the nozzle 249a, and the etching efficiency can be enhanced. By increasing the etching rate in the vicinity (particularly on the back surface side) of the nozzle 249a, the deposit adhered to the side surface of the nozzle 249a can be efficiently removed.

In addition, the nozzles 249a and 249b are provided at positions adjacent to each other along the circumferential direction of the wafer 200. Accordingly, the FNO or the like can be preferentially and reliably generated in the vicinity of the nozzle 249a.

In addition, in the cleaning step, the additive gas is supplied into the process chamber 201 by using the nozzle 249b including the plurality of gas discharge holes 250b1 formed from one end side to the other end side in the wafer arrangement direction. Accordingly, the FNO or the like can be preferentially generated in the vicinity of the nozzle 249a from one end side to the other end side in the wafer arrangement direction.

In addition, in the cleaning step, the additive gas is supplied into the process chamber 201 by using the nozzle 249b including the gas discharge holes 250b1 opened to be directed toward the back surface of the nozzle 249a. Accordingly, the FNO or the like can be preferentially generated on the back surface side of the nozzle 249a. Therefore, the etching rate can be increased on the back surface side of the nozzle 249a where the source and the reactant are likely to accumulate and the deposit is likely to adhere.

In addition, in the cleaning step, the additive gas is supplied into the process chamber 201 by using the nozzle 249b including the gas discharge hole 250b2. Accordingly, the FNO or the like can be preferentially generated in the upper dome space in the process chamber 201. Therefore, the etching rate can be increased in the upper dome space where the source and the reactant are likely to stagnate and the deposit is likely to adhere, and the etching efficiency can be enhanced. As a result, the deposit adhered to the inner wall surface of the lid of the reaction tube 203 can be efficiently removed.

The nozzle 249b that supplies the additive gas is more susceptible to etching damage than the nozzle 249a that supplies the first cleaning gas. Therefore, in the cleaning step, the additive gas is supplied into the process chamber 201 by using the nozzle 249b different from the nozzle 249a that supplies the source. In addition, the nozzle 249b that supplies the additive gas is detachably provided with respect to the reaction tube 203. As a result, even in cases where the nozzle 249b is subjected to etching damage, the possibility of affecting the substrate processing using the nozzle 249a can be reduced. For example, even in cases where the nozzle 249b is subjected to etching damage due to intrusion or supply of the first cleaning gas into the nozzle 249b, replacement of the nozzle 249b can be easily performed.

In addition, in the cleaning step, the first cleaning gas is supplied into the process chamber 201 by using the nozzle 249a that supplies the source. Accordingly, the source derived substance adhered to the inside of the nozzle 249a and the deposit formed on the inner wall surface of the nozzle 249a due to the intrusion or the like of the reactant into the nozzle 249a can be removed.

As the first cleaning gas, for example, a gas containing halogen can be used. As the gas containing halogen, for example, a fluorine-based gas can be used. As the fluorine-based gas, for example, a fluorine (F₂) gas, a chlorine trifluoride (CIF₃) gas, a chlorine monofluoride (CIF) gas, or a nitrogen trifluoride (NF₃) gas can be used. One or more of these gases can be used as the first cleaning gas.

As the additive gas, for example, a nitrogen oxide-based gas can be used. As the nitrogen oxide-based gas, for example, a nitric oxide (NO) gas or a nitrous oxide (N₂O) gas can be used. One or more of these gases can be used as the additive gas.

As the additive gas, in addition to the nitrogen oxide-based gas, for example, a hydrogen (H₂) gas, an oxygen (O₂) gas, an isopropyl alcohol ((CH₃)₂CHOH) gas, a methanol (CH₃OH) gas, or a water vapor (H₂O gas) can be used. One or more of these gases can be used as the additive gas.

### (After-Purge and Atmospheric Pressure Restoration)

When cleaning of the inside of the process container is completed, the APC valve 244 is opened, and the inert gas is supplied into the process chamber 201 from each of the nozzles 249a to 249c and is exhausted from the exhaust port 231a. Accordingly, the inside of the process chamber 201 is purged, and a gas, a by-product, and the like remaining in the process chamber 201 after cleaning are removed from the inside of the process chamber 201 (after-purge). Thereafter, the atmosphere in the process chamber 201 is replaced with the inert gas (inert gas replacement), so that the pressure in the process chamber 201 is restored to a normal pressure (atmospheric pressure restoration).

### (Boat Unload)

Thereafter, the seal cap 219 is lowered by the boat elevator 115, and the lower end of the reaction tube 203 is opened. Then, the empty boat 217 is unloaded to the outside of the reaction tube 203 from the lower end of the reaction tube 203 (boat unload). When the series of processes are finished, the above-described substrate processing is resumed.

### (4) Effects of Embodiments

According to the embodiments, one or more of the following effects can be obtained.

(a) In the source supply step, while the source is supplied into the process chamber 201 from the nozzle 249a (during execution of step A), the inert gas is discharged into the process chamber 201 by using the nozzle 249b including the gas discharge holes 250b1 that are opened toward at least one of (i) the portion of the side surface of the nozzle 249a in a range different from the range where the gas discharge holes 250a are formed and (ii) the space between the portion of the nozzle 249a in the range different from the range where the gas discharge holes 250a are formed and the inner wall surface of the reaction tube 203. Accordingly, during the supply of the source, the side surface of the nozzle 249a (for example, the portion of the side surface of the nozzle 249a other than the range where the gas discharge holes 250a are formed) can be purged with the inert gas. As a result, it is possible to prevent the source derived substance from adhering to the side surface of the nozzle 249a. In addition, by preventing adhesion of the source derived substance to the side surface of the nozzle 249a, it is possible to prevent the reaction between the source derived substance adhered to the side surface of the nozzle 249a and the reactant in the reactant supply step. Accordingly, it is possible to prevent the deposit containing the source derived substance, a substance generated by the reaction between the source derived substance and the reactant, and the like from adhering to the side surface of the nozzle 249a. As a result, it is possible to prevent generation of particles and the like, and it is possible to suppress a reduction in film quality and the like finally formed on the wafer 200.

In addition, in the reactant supply step, while the reactant is supplied into the process chamber 201 via the nozzle 249c (during execution of step B), the inert gas is discharged into the process chamber 201 by using the nozzle 249b including the gas discharge holes 250b1 described above. Accordingly, during the supply of the reactant, the side surface of the nozzle 249a can be purged with the inert gas. As a result, even in cases where the source derived substance has adhered to the side surface of the nozzle 249a in the source supply step, it is possible to prevent the reaction between the source derived substance adhered to the side surface of the nozzle 249a and the reactant in the reactant supply step. By preventing such a reaction, it is possible to reliably prevent a substance generated by the reaction between the source derived substance and the reactant from adhering to the side surface of the nozzle 249a. Accordingly, it is possible to reliably prevent the generation of particles and the like.

In addition, in the cleaning step, the additive gas is supplied into the process chamber 201 by using the nozzle 249b including the gas discharge holes 250b1 described above. Accordingly, the FNO or the like can be preferentially generated in the vicinity of the nozzle 249a. Therefore, the etching rate can be increased in the vicinity of the nozzle 249a, and the etching efficiency can be enhanced. As a result, the deposit adhered to the side surface of the nozzle 249a can be efficiently removed.

(b) In the source supply step, during the supply of the source, the inert gas is discharged into the process chamber 201 by using the nozzle 249b including the gas discharge holes 250b1 opened to be directed toward the back surface of the nozzle 249a. Accordingly, during the supply of the source, the back surface side of the nozzle 249a where the source is likely to stagnate can be purged with the inert gas. As a result, it is possible to prevent the source from stagnating on the back surface side of the nozzle 249a. By preventing the stagnation of the source on the back surface side of the nozzle 249a, it is possible to reliably prevent the source from adhering to the back surface side of the nozzle 249a. As a result, it is possible to reliably prevent the substance containing the source and the reactant from adhering to the side surface of the nozzle 249a.

In addition, in the cleaning step, the additive gas is supplied into the process chamber 201 by using the nozzle 249b including the gas discharge holes 250b1 opened to be directed toward the back surface of the nozzle 249a. Accordingly, the FNO or the like can be preferentially generated on the back surface side of the nozzle 249a. Therefore, the etching rate can be increased on the back surface side of the nozzle 249a where the source and the reactant are likely to accumulate and the deposit is likely to adhere. As a result, the deposit adhered to the side surface of the nozzle 249a can be more efficiently removed.

(c) In the source supply step, the inert gas is discharged into the process chamber 201 by using the nozzle 249b including the gas discharge hole 250b2. Accordingly, during the supply of the source, the upper dome space in the process chamber 201 where the source is likely to stagnate can be efficiently purged with the inert gas. As a result, it is possible to prevent the source from adhering to the inner wall surface of the lid of the reaction tube 203.

In the cleaning step, the additive gas is supplied into the process chamber 201 by using the nozzle 249b including the gas discharge hole 250b2. Accordingly, the FNO or the like can be preferentially generated in the upper dome space in the process chamber 201. Therefore, the etching rate can be increased in the upper dome space where the source and the reactant are likely to stagnate and the deposit is likely to adhere, and the etching efficiency can be enhanced. As a result, the deposit adhered to the inner wall surface of the lid of the reaction tube 203 can be efficiently removed.

(d) In the source supply step, the inert gas is discharged into the process chamber 201 by using the nozzle 249b not including the gas discharge hole opened toward the wafer arrangement region. Accordingly, during the supply of the source, dilution of the source supplied from the nozzle 249a in the process chamber 201 can be suppressed. As a result, it is possible to prevent the inert gas supplied from the nozzle 249b from affecting the formation rate of the layer formed on the wafer 200, the thickness and quality of the film finally formed on the wafer 200, and the like, in the source supply step.

(e) In the source supply step, the flow rate (second flow rate) of the inert gas caused to flow into the gas supply pipe 232b at the time of performing purge is set to be larger than the flow rate (first flow rate) of the inert gas caused to flow into the gas supply pipe 232b at the time of supplying the source (during execution of step A′). Accordingly, the upper dome space in the process chamber 201 can be efficiently purged. As a result, it is possible to suppress the film formation from being affected by the source remaining in the upper dome space in the process chamber 201.

(f) The above-described effects can be similarly obtained even in cases of using a simultaneous supply method of simultaneously supplying the source and the reactant to the wafer 200 in the film forming step. In addition, the above-described effects can be similarly obtained even in cases of using an alternate supply method of non-simultaneously and alternately supplying the first cleaning gas and the additive gas in the cleaning step.

(g) The above-described effects can be similarly obtained even in cases where predetermined substances (gaseous substances or liquid substances) are optionally selected and used from the various sources, various reactants, various inert gases, various first cleaning gases, and various additive gases described above.

### (5) MODIFIED EXAMPLES

The substrate processing sequence in some embodiments can be modified as in the following modified examples. These modified examples can be optionally combined. Unless otherwise specifically described, processing procedures and processing conditions in each step of each of the modified examples can be similar to the processing procedures and processing conditions in each step of the substrate processing sequence described above.

### Modified Example 1

As in the following cleaning sequence, in the cleaning step, the first cleaning gas may be supplied to one of the nozzles 249a and 249b, and a second cleaning gas with a composition different from that of the first cleaning gas (for example, with a different molecular structure) may be supplied to the other of the nozzles 249a and 249b, which is different from the one nozzle.
(R1: first cleaning gas+R2: second cleaning gas)
(R1: second cleaning gas+R2: first cleaning gas)

In cases where the second cleaning gas is supplied from the nozzle 249a, a second cleaning gas supply system can mainly include the gas supply pipe 232d, the MFC 241d, and the valve 243d. In cases where the second cleaning gas is supplied from the nozzle 249b, the second cleaning gas supply system can mainly include the gas supply pipe 232e, the MFC 241e, and the valve 243e.

As the second cleaning gas, for example, a gas containing H and F (a fluorine-based gas containing H) can be used. As the gas containing H and F, for example, a hydrogen fluoride (HF) gas can be used.

Processing procedures and processing conditions at the time of supplying the first cleaning gas and the second cleaning gas can be similar to the processing procedures and processing conditions at the time of supplying the first cleaning gas in the embodiments described above.

Also in the present modified example, the effects similar to those in the above embodiments can be obtained. That is, by supplying the first cleaning gas or the second cleaning gas into the process chamber 201 by using the nozzle 249b, the deposit adhered to the side surface of the nozzle 249a can be efficiently removed. In addition, in the present modified example, a plurality of different types (for example, two types) of cleaning gases are used in the cleaning step. Accordingly, the deposit adhered to the surfaces of the members in the process container can be more efficiently removed.

### Modified Example 2

As in the following cleaning sequence, in the cleaning step, the first cleaning gas or the second cleaning gas may be supplied to the nozzle 249b, which is one of the nozzles 249a and 249b, and the inert gas may be supplied into the process chamber 201 from the nozzle 249a, which is the other nozzle, different from the nozzle 249b as the one nozzle. Processing procedures and processing conditions at the time of supplying the first cleaning gas or the second cleaning gas can be similar to those at the time of supplying the first cleaning gas in the cleaning step in the above embodiments.
(R1: inert gas+R2: first cleaning gas)
(R1: inert gas+R2: second cleaning gas)

Also in the present modified example, the effects similar to those in the above embodiments can be obtained. That is, by supplying the first cleaning gas or the second cleaning gas into the process chamber 201 by using the nozzle 249b, the deposit adhered to the side surface of the nozzle 249a can be efficiently removed.

### Modified Example 3

As in the following cleaning sequence, in the cleaning step, the first cleaning gas or the second cleaning gas may be supplied to any one of the nozzles 249a to 249c, and the additive gas or the second cleaning gas may be supplied to another nozzle different from the one of the nozzles 249a to 249c. Processing procedures and processing conditions at the time of supplying the first cleaning gas or the second cleaning gas can be similar to those at the time of supplying the first cleaning gas in the cleaning step in the above embodiments. In addition, processing procedures and processing conditions at the time of supplying the additive gas and the inert gas can be similar to those in the cleaning step in the above embodiments.
(R1: inert gas+R2: first cleaning gas+R3: additive gas)
(R1: inert gas+R2: second cleaning gas+R3: additive gas)
(R1: inert gas+R2: additive gas+R3: first cleaning gas)
(R1: inert gas+R2: additive gas+R3: second cleaning gas)

Also in the present modified example, the effects similar to those in the above embodiments can be obtained. That is, by supplying any one of the first cleaning gas, the second cleaning gas, and the additive gas into the process chamber 201 by using the nozzle 249b, the FNO or the like can be preferentially generated in the vicinity of the nozzle 249a. Accordingly, the deposit adhered to the side surface of the nozzle 249a can be efficiently removed.

Furthermore, the cleaning sequence may be changed as described in the following cleaning sequence.
(R1: first cleaning gas+R2: inert gas+R3: additive gas)
(R1: second cleaning gas+R2: inert gas+R3: additive gas)

### Modified Example 4

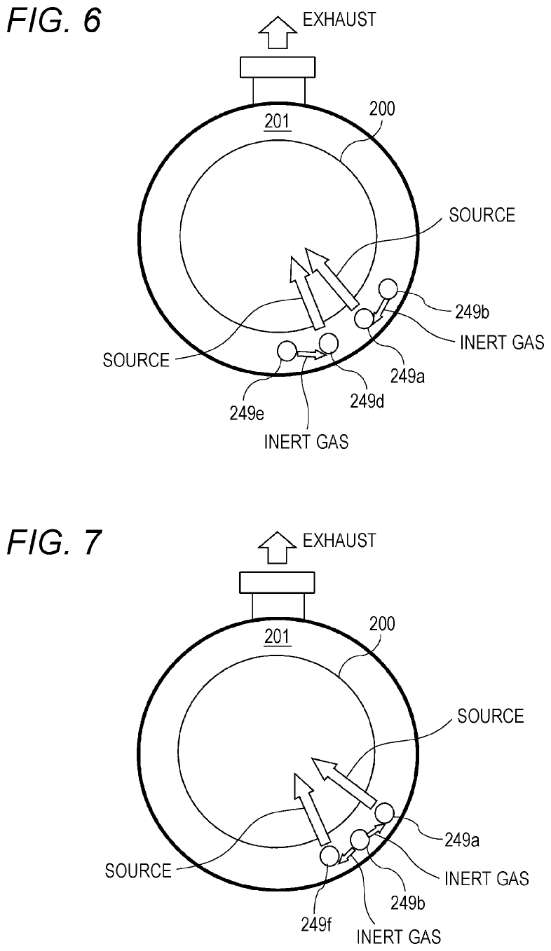

For example, as illustrated in FIG. 6, in addition to the first to third suppliers, nozzles 249d and 249e serving as fourth and fifth suppliers, respectively, may be provided in the process chamber 201. The nozzles 249d and 249e are also referred to as fourth and fifth nozzles, respectively.

A fourth discharge hole serving as a fourth discharge opening from which a gas is discharged is formed in a side surface of the nozzle 249d. The configuration of the fourth discharge hole can be similar to the configuration of the first discharge hole formed in the side surface of the nozzle 249a described above.

The nozzle 249e is detachably provided with respect to the reaction tube 203. A fifth discharge hole serving as a fifth discharge opening from which a gas is discharged is formed in a side surface of the nozzle 249e. The fifth discharge hole is opened to be directed toward at least one of (i) a portion of the side surface of the nozzle 249d in a range different from a range where the fourth discharge hole is formed and (ii) a space between the portion of the nozzle 249d in the range different from the range where the fourth discharge hole is formed and the inner wall surface of the reaction tube 203. Other configurations of the nozzle 249e can be similar to those of the nozzle 249b described above.

In the present modified example, the source supply system is configured to supply the source into the process chamber 201 via the nozzles 249a and 249d, and the inert gas supply system is configured to supply the inert gas into the process chamber 201 via the nozzles 249b and 249e. In addition, the first cleaning gas supply system is configured to supply the first cleaning gas into the process chamber 201 via the nozzles 249a and 249d, and the additive gas supply system is configured to supply the additive gas into the process chamber 201 via the nozzles 249b and 249e.

Also in the present modified example, the effects similar to those in the above embodiments and modified examples can be obtained. That is, during the supply of the source and during the supply of the reactant, by discharging the inert gas from the nozzles 249b and 249e, the side surfaces of the nozzles 249a and 249d (for example, the portion of the side surface of the nozzle 249a other than the range where the first discharge hole is formed and the portion of the side surface of the nozzle 249d other than the range where the fourth discharge hole is formed) can be purged with the inert gas. In addition, during cleaning, by supplying the additive gas into the process chamber 201 from the nozzles 249b and 249e, the etching rate can be increased in the vicinity of the nozzles 249a and 249d, and the etching efficiency can be enhanced.

The first cleaning gas or the second cleaning gas may be supplied from the nozzles 249b and 249e.

### Modified Example 5

For example, as illustrated in FIG. 7, in addition to the first to third suppliers, a nozzle 249f serving as a sixth supplier may be provided in the process chamber 201. The nozzle 249f is also referred to as a sixth nozzle. A sixth discharge hole serving as a sixth discharge opening from which a gas is discharged is formed in a side surface of the nozzle 249f. The configuration of the sixth discharge hole can be similar to the configuration of the first discharge hole formed in the side surface of the nozzle 249a described above.

In the present modified example, in addition to the second discharge hole, a seventh discharge hole serving as a seventh discharge opening is further formed in the side surface of the nozzle 249b. The seventh discharge hole is opened to be directed toward at least one of (i) a portion of the side surface of the nozzle 249f in a range different from a range where the sixth discharge hole is formed and (ii) a space between the portion of the nozzle 249f in the range different from the range where the sixth discharge hole is formed and the inner wall surface of the reaction tube 203. Other configurations of the seventh discharge hole can be similar to the configuration of the second discharge hole (gas discharge holes 250b1) formed in the side surface of the nozzle 249b described above.

In addition, in the present modified example, the source supply system is configured to supply the source into the process chamber 201 via the nozzles 249a and 249f. In addition, the first cleaning gas supply system is configured to supply the first cleaning gas into the process chamber 201 via the nozzles 249a and 249f.

Also in the present modified example, the effects similar to those in the above embodiments and modified examples can be obtained. That is, during the supply of the source and during the supply of the reactant, by discharging the inert gas from the second discharge hole and the seventh discharge hole of the nozzle 249b, the side surfaces of the nozzles 249a and 249f (for example, the portion of the side surface of the nozzle 249a other than the range where the first discharge hole is formed and the portion of the side surface of the nozzle 249f other than the range where the sixth discharge hole is formed) can be purged with the inert gas. In addition, during cleaning, by supplying the first cleaning gas, the second cleaning gas, or the additive gas from the second discharge hole and the seventh discharge hole of the nozzle 249b, the etching rate can be increased in the vicinity of the nozzles 249a and 249f, and the etching efficiency can be enhanced.

### Modified Example 6

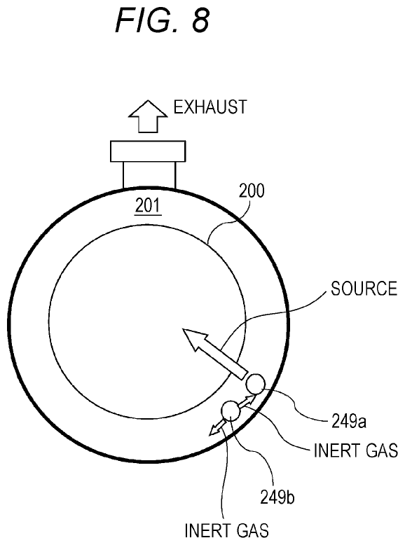

For example, as illustrated in FIG. 8, in addition to the second discharge hole, an eighth discharge hole serving as an eighth discharge opening may be further formed in the side surface of the nozzle 249b. The eighth discharge hole is opened in a portion of the side surface of the nozzle 249b in a range different from a position facing the wafer arrangement region and in a range different from the range where the second discharge hole is formed. More preferably, the eighth discharge hole is opened so as not to be directed toward either the portion of the side surface of the nozzle 249a in a range different from the range where the first discharge hole is formed or a space between the portion of the nozzle 249a in a range different from the range where the first discharge hole is formed and the inner wall surface of the reaction tube 203. For example, as illustrated in FIG. 8, the eighth discharge hole is formed in a portion of the side surface of the nozzle 249b in a circumferential direction, the portion is substantially opposite to the gas discharge holes 250b1. In addition, the eighth discharge hole is opened to be directed toward the inner wall surface of the reaction tube 203. Therefore, the gas can be discharged toward the inner wall surface of the reaction tube 203. Other configurations of the eighth discharge hole can be similar to the configuration of the second discharge hole formed in the side surface of the nozzle 249b described above.

Also in the present modified example, the effects similar to those in the above embodiments can be obtained. Furthermore, in the present modified example, it is possible to prevent adhesion of the source derived substance to the inner wall surface of the reaction tube 203 during the supply of the source, and it is possible to prevent a substance generated by the reaction between the source derived substance and the reactant from adhering to the inner wall surface of the reaction tube 203. In addition, in the present modified example, the etching rate can be increased in the vicinity of the inner wall surface of the reaction tube 203 during cleaning, and the deposit adhered to the inner wall surface of the reaction tube 203 can be efficiently removed.

### Other Embodiments of the Present Disclosure

Some embodiments of the present disclosure have been specifically described above. However, the present disclosure is not limited to the above embodiments, and various modifications can be made without departing from the gist thereof.

For example, the present disclosure can also be applied to cases where a film containing a semiconductor element such as silicon (Si) or germanium (Ge), or a metal element such as zirconium (Zr), hafnium (Hf), tantalum (Ta), aluminum (AI), molybdenum (Mo), tungsten (W), or ruthenium (Ru) is formed on a substrate as a main element. Processing procedures and processing conditions at the time of supplying the film-forming agent can be similar to those in each step in the above embodiments. Also in these cases, the effects similar to those in the above embodiments can be obtained.

In addition, for example, the present disclosure can also be applied to cases where a film containing an element such as oxygen (O), carbon (C), nitrogen (N), or boron (B) is formed on a substrate. For example, the present disclosure can also be applied to cases where a silicon dioxide film (SiO film), a silicon oxycarbide film (SiOC film), a silicon oxycarbonitride film (SiOCN film), a silicon carbonitride film (SiCN film), a silicon boronitride film (SiBN film), a silicon boron carbonitride film (SiBCN film), or the like is formed on a substrate by the above-described processing sequence by using a nitrogen-containing gas described above, an oxygen-containing gas such as an H₂O gas, a hydrogen peroxide (H₂O₂) gas, a hydrogen (H₂) gas+oxygen (O₂) gas, or an ozone (O₃) gas, a carbon-containing gas such as an ethylene (C₂H₄) gas, an acetylene (C₂H₂) gas, or a propylene (C₃H₆) gas, a nitrogen and carbon-containing gas such as a triethylamine ((C₂H₅)₃N) gas or a trimethylamine ((CH₃)₃N,) gas, or a boron-containing gas such as a diborane (B₂H₆) gas or a trichloroborane (BCl₃) gas as a reactant. Processing procedures and processing conditions at the time of supplying the film-forming agent can be similar to those in each step in the above embodiments. Also in these cases, the effects similar to those in the above embodiments can be obtained.

In the present specification, the description of two gases such as “H₂ gas+O₂ gas” means a mixed gas of H₂ gas and O₂ gas. In cases of supplying the mixed gas, the two gases may be mixed (premixed) in the supply pipe and then supplied into the process chamber 201, or the two gases may be separately supplied into the process chamber 201 from different supply pipes and mixed (post-mixed) in the process chamber 201.

Preferably, the recipe used in each process is individually prepared according to processing contents and is recorded and stored in the memory 121c via an electric communication line or the external memory 123. Then, when each process is started, the CPU 121a preferably appropriately selects an appropriate recipe from among the plurality of recipes recorded and stored in the memory 121c according to the processing contents. Accordingly, it is possible to form films with various film types, composition ratios, film qualities, and thicknesses of film with good reproducibility by using one substrate processing apparatus. In addition, it is possible to reduce a burden on an operator, and it is possible to quickly start each process while avoiding an operation error.

The recipe described above is not limited to a newly created recipe, but may be prepared by, for example, changing the existing recipe already installed in the substrate processing apparatus. When changing the recipe, the changed recipe may be installed in the substrate processing apparatus through an electric communication line or a recording medium in which the recipe is recorded. In addition, the existing recipe already installed in the substrate processing apparatus may be directly changed by operating the input/output device 122 included in the existing substrate processing apparatus.

In the above embodiments, an example has been described in which each of the first to eighth discharge holes includes a plurality of discharge holes. The present disclosure is not limited to the above embodiments, and at least one selected from the group of the first to eighth discharge holes may include one or a plurality of slit-shaped holes formed in the side surface of the nozzle so as to extend in an extending direction of the nozzle (that is, in the arrangement direction of the substrates), for example.

In the above embodiments, an example has been described in which a film is formed by using a batch-type substrate processing apparatus that processes a plurality of substrates at a time. The present disclosure is not limited to the above embodiments, and can be suitably applied to cases of forming a film by using a single wafer type substrate processing apparatus that processes one or more substrates at a time, for example. In addition, in the above embodiments, an example has been described in which a film is formed by using a substrate processing apparatus including a hot wall-type process furnace. The present disclosure is not limited to the above embodiments, and can be suitably applied to cases of forming a film by using a substrate processing apparatus including a cold wall-type process furnace.

Even in cases where such substrate processing apparatuses are used, each process can be performed in accordance with processing procedures and processing conditions similar to those in the above embodiments and modified examples, leading to obtainment of effects similar to those in the above embodiments and modified examples.

The above embodiments and modified examples can be used in combination as appropriate. Processing procedures and processing conditions at that time can be similar to the processing procedures and processing conditions in the above embodiments and modified examples, for example.

According to the present disclosure, it is possible to prevent adhesion of a deposit to a surface of a member in the process container.

What is claimed is:

1. A substrate processing apparatus comprising:
a process container accommodating a substrate;
a first nozzle including a side surface in which a first discharge opening is formed, the first discharge opening directed toward a substrate arrangement region where the substrate is arranged in the process container;
a second nozzle including a side surface in which a second discharge opening is formed, the second discharge opening directed toward at least one of a portion of the side surface of the first nozzle in a range different from a range where the first discharge opening is formed and a space between the portion in the range different from the range where the first discharge opening is formed and an inner wall surface of the process container;
a source gas supply system configured to supply a source gas into the process container via the first nozzle; and
an inert gas supply system configured to supply an inert gas into the process container via the second nozzle.

2. The substrate processing apparatus according to claim 1, wherein:
a plurality of substrates including the substrate are arranged in the substrate arrangement region at a predetermined interval in a direction perpendicular to a surface of the substrate; and wherein,
the first nozzle and the second nozzle are provided along an arrangement direction of the plurality of substrates at positions adjacent to each other along a circumferential direction of the substrate.

3. The substrate processing apparatus according to claim 1, wherein the second discharge opening is formed so as to discharge the inert gas toward a portion of the side surface of the first nozzle being opposite, in a radial direction of the first nozzle, to the range where the first discharge opening is formed.

4. The substrate processing apparatus according to claim 1, wherein the second nozzle does not include a discharge opening at a position facing the substrate arrangement region.

5. The substrate processing apparatus according to claim 1, wherein the second nozzle is configured to be detachable with respect to the process container.

6. The substrate processing apparatus according to claim 1, further comprising a controller configured to be capable of controlling the source gas supply system and the inert gas supply system so as to supply the inert gas into the process container while the source gas is supplied into the process container.

7. The substrate processing apparatus according to claim 1, wherein a plurality of substrates including the substrate are arranged in the substrate arrangement region at a predetermined interval in a direction perpendicular to a surface of the substrate; and wherein,
the second nozzle further includes an upper discharge opening that is opened to be directed toward a space above the substrate arrangement region.

8. The substrate processing apparatus according to claim 7, wherein the upper discharge opening is formed in a distal end of the second nozzle.

9. The substrate processing apparatus according to claim 7, wherein an opening area of the upper discharge opening is larger than an opening area of the second discharge opening.

10. The substrate processing apparatus according to claim 7, further comprising:
a third nozzle including a side surface in which a third discharge opening is formed;
a reactant gas supply system configured to supply a reactant gas into the process container via the third nozzle; and
a controller configured to be capable of controlling the source gas supply system, the reactant gas supply system, and the inert gas supply system so as to perform processing of forming a film on the substrate accommodated in the process container by performing a cycle a predetermined number of times, the cycle including (a) supplying the source gas into the process container and (b) supplying the reactant gas into the process container, in which the inert gas is supplied from the second nozzle at a first flow rate in (a), and the inert gas is supplied from the second nozzle at a second flow rate larger than the first flow rate between (a) and (b).

11. The substrate processing apparatus according to claim 1, further comprising a first cleaning gas supply system configured to supply a first cleaning gas to one of the first nozzle and the second nozzle.

12. The substrate processing apparatus according to claim 11, further comprising an additive gas supply system configured to supply an additive gas that reacts with the first cleaning gas to another nozzle different from the one of the first nozzle and the second nozzle.

13. The substrate processing apparatus according to claim 11, further comprising a second cleaning gas supply system configured to supply a second cleaning gas with a composition different from a composition of the first cleaning gas to another nozzle different from the one of the first nozzle and the second nozzle.

14. The substrate processing apparatus according to claim 1, further comprising:
a third nozzle including a side surface in which a third discharge opening is formed;
a reactant gas supply system configured to supply a reactant gas into the process container via the third nozzle;
a first cleaning gas supply system configured to supply a first cleaning gas to any one of the first nozzle, the second nozzle, and the third nozzle; and
an additive gas supply system configured to supply an additive gas that reacts with the first cleaning gas to another nozzle different from the one of the first nozzle, the second nozzle, and the third nozzle.

15. The substrate processing apparatus according to claim 1, further comprising:
a fourth nozzle including a side surface in which a fourth discharge opening is formed, the fourth discharge opening directed toward the substrate arrangement region; and
a fifth nozzle including a side surface in which a fifth discharge opening is formed, the fifth discharge opening directed toward at least one of a portion of the side surface of the fourth nozzle in a range different from a range where the fourth discharge opening is formed and a space between the portion in the range different from the range where the fourth discharge opening is formed and the inner wall surface of the process container; wherein,
the source gas supply system is configured to supply the source gas into the process container via the first nozzle and the fourth nozzle; and
the inert gas supply system is configured to supply the inert gas into the process container via the second nozzle and the fifth nozzle.

16. The substrate processing apparatus according to claim 1, further comprising:
a sixth nozzle including a side surface in which a sixth discharge opening is formed, the sixth discharge opening directed toward the substrate arrangement region; wherein,
in the side surface of the second nozzle, a seventh discharge opening is further formed, the seventh discharge opening directed toward at least one of a portion of the side surface of the sixth nozzle in a range different from a range where the sixth discharge opening is formed and a space between the portion in the range different from the range where the sixth discharge opening is formed and the inner wall surface of the process container; and
the source gas supply system is configured to supply the source gas into the process container via the first nozzle and the sixth nozzle.

17. The substrate processing apparatus according to claim 1, wherein in the side surface of the second nozzle, an eighth discharge opening is further formed, the eighth discharge opening directed in a portion of the side surface in a range different from a range facing the substrate arrangement region and in a range different from a range where the second discharge opening is formed.

18. A method of manufacturing a semiconductor device, comprising:
(a) supplying a source gas into a process container via a first nozzle including a side surface in which a first discharge opening is formed, the first discharge opening directed toward a substrate arrangement region where a substrate is arranged in the process container;
(a′) supplying an inert gas from a second nozzle different from the first nozzle toward at least one of a portion of the side surface of the first nozzle in a range different from a range where the first discharge opening is formed and a space between the portion in the range different from the range where the first discharge opening is formed and an inner wall surface of the process container in (a).

19. A non-transitory computer-readable recording medium storing a program that causes, by a computer, a substrate processing apparatus to perform a process comprising:
(a) supplying a source gas into a process container via a first nozzle including a side surface in which a first discharge opening is formed, the first discharge opening directed toward a substrate arrangement region where a substrate is arranged in the process container; and
(a′) supplying an inert gas from a second nozzle different from the first nozzle toward at least one of a portion of the side surface of the first nozzle in a range different from a range where the first discharge opening is formed and a space between the portion in the range different from the range where the first discharge opening is formed and an inner wall surface of the process container in (a).
